(19) United States
(12) Patent Application Publication
(10) Pub. No.: US 2007/0277931 A1
(43) Pub. Date: Dec. 6, 2007

(54) Semiconductor substrate processing apparatus, method, and medium

(75) Inventors: Myoung Woon Kim, Suwon-si (KR); Moon Hyeong Han, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRONICS CO., LTD., Suwon-si (KR)

(21) Appl. No.: 11/727,182

(22) Filed: Mar. 23, 2007

(30) Foreign Application Priority Data
Jun. 5, 2006 (KR) 2006-0050598

(51) Int. Cl. C23F 1/00; H01L 21/306

(52) U.S. Cl. 156/345.48

(57) ABSTRACT

A semiconductor substrate processing apparatus can supply RF powers having the same frequency to upper and lower electrodes serving to generate different degrees of uniformity, and control a power ratio of the RF powers, thereby enhancing a processing uniformity of a semiconductor substrate. The apparatus includes a vacuum chamber to receive a semiconductor substrate, upper and lower electrodes disposed within the vacuum chamber, RF power suppliers to supply RF powers having the same frequency to the upper and lower electrodes, and a controller to control a power ratio of the RF powers supplied from the RF power suppliers to the upper and lower electrodes.

### CROSS-REFERENCE TO RELATED APPLICATIONS

This application claims the benefit of Korean Patent Application No. 2006-0050598, filed on Jun. 5, 2006 in the Korean Intellectual Property Office, the disclosure of which is incorporated herein by reference.

### BACKGROUND OF THE INVENTION

1. Field of the Invention

The present invention relates to etching and deposition processes among a semiconductor manufacturing process by use of plasma, and, more particularly, to a semiconductor substrate processing apparatus, method, and medium, which has enhanced uniformity of process plasma to control etching uniformity.

2. Description of the Related Art

Generally, a semiconductor manufacturing process includes a plasma etching or deposition process in which a semiconductor substrate as a target substrate is subjected to etching or deposition by plasma. Among various plasma etching apparatuses or plasma deposition apparatuses, a planar inductively coupled plasma processing apparatus is generally used.

The planar inductively coupled plasma processing apparatus includes a pair of planar electrodes (upper and lower electrodes) disposed in parallel in a vacuum chamber to generate an RF (radio frequency) electric field between the electrodes by application of RF to one of the electrodes while supplying a process gas into the vacuum chamber. The RF electric field causes the gas within the reaction chamber to be excited to plasma, which emanates ions and electrons, such that a semiconductor substrate is subjected to etching and deposition as a semiconductor pre-process by use of the ions and electrons of the plasma.

For such a semiconductor pre-process, the vacuum chamber employs a high power RF power supplier, which supplies RF power to the electrode of the chamber in order to excite the gas in the reaction chamber to the plasma. Here, a frequency and power of the RF power supplier influence characteristics of the process.

Initially, the vacuum chamber employed a single RF power supplier. However, as a semiconductor substrate has increased in its degree of integration, characteristics required for a semiconductor substrate process have also increased. In this regard, a semiconductor substrate processing apparatus employing two frequencies has been developed, and in recent years, a semiconductor substrate processing apparatus employing three frequencies has been developed.

FIG. 1A shows an RF power supply system for a semiconductor substrate processing apparatus disclosed in U.S. Pat. No. 6,423,242, as one of the semiconductor substrate processing apparatuses employing the two frequencies.

In FIG. 1A, two RF power suppliers 7 and 9 are respectively connected to upper and lower electrodes 3 and 5 disposed in parallel within a vacuum chamber 1 such that different RF powers are supplied to the upper and lower electrodes 3 and 5. Among the RF powers, an RF power having a lower frequency is used to control energy of ions among components of plasma, and an RF power having a higher frequency is used to control a density of the ions, thereby enhancing an etching rate (or a deposition rate).

FIG. 2A shows an RF power supply system for a semiconductor substrate processing apparatus disclosed in U.S. Pat. No. 4,579,618, as another semiconductor substrate processing apparatus which employs the two frequencies.

In FIG. 2A, two RF power suppliers 15 and 17 are connected to a lower electrode 13 disposed within a vacuum chamber 11 such that different RF powers are supplied only to the lower electrode 13. An RF power having a lower frequency is used to control energy of ions among components of plasma, and an RF power having a higher frequency is used to control a density of the ions, thereby enhancing an etching rate (or a deposition rate).

Meanwhile, as the semiconductor process requires a higher etching rate, a higher plasma density is required (since a higher plasma density enhances the etching rate). Accordingly, the RF power supply systems adapted to employ the two different frequencies as shown in FIGS. 1A and 2A have been modified to employ a higher frequency. However, for the RF power supply system employing the high frequency, the high frequency generates a sine wave at the electrodes 3 and 5 or 13, causing a problem in etching uniformity of the process, as shown in FIGS. 1B and 2B.

In addition, since the conventional system cannot adjust a power ratio of RF powers supplied to the electrodes 3 and 5 or 13, the conventional system suffers from a failure in adjustment of etching uniformity.

In order to solve these problems, there has been suggested a technique which comprises a modified upper electrode to achieve a process uniformity. However, there is a problem in that this technique cannot cope with variation in uniformity resulting from variation in conditions of the semiconductor substrate processing.

### SUMMARY OF THE INVENTION

The present invention has been made in view of the above and other problems, and an aspect of the present invention is to provide a semiconductor substrate processing apparatus, which can supply RF powers having the same frequency to upper and lower electrodes serving to generate different degrees of uniformity, and which can control a power ratio of the RF powers, thereby enhancing a processing uniformity on a semiconductor substrate.

Additional aspects, features, and/or advantages of the invention will be set forth in part in the description which follows and, in part, will be apparent from the description, or may be learned by practice of the invention.

In accordance with one aspect of the present invention, there is provided a semiconductor substrate processing apparatus, including: a vacuum chamber to receive a semiconductor substrate; upper and lower electrodes disposed within the vacuum chamber; an RF power supplier (radio frequency) to supply RF powers having the same frequency to the upper and lower electrodes; and a controller to control a power ratio of the RF powers supplied from the RF power supplier to the upper and lower electrodes.

The RF power supplier may include a pair or more of high frequency power suppliers connected to the upper and lower electrodes.

Each of the high frequency power suppliers may have a usable frequency of 2 MHz or more.

The RF power supplier may further include a low frequency power supplier connected to the lower electrode.

The low frequency power supplier may have a usable frequency lower than that of the high frequency power suppliers.

In accordance with another aspect of the present invention, there is provided a semiconductor substrate processing apparatus, including a vacuum chamber to receive a semiconductor substrate; a gas supplier to supply gas for processing a semiconductor substrate in the vacuum chamber; a RF (radio frequency) power supplier to supply RF powers to generate plasma from the supplied gas; and a controller to control amounts of RF powers and a ratio of the RF powers supplied to upper and lower electrodes disposed in the vacuum chamber.

The controller may allow high RF powers having the same frequency to be supplied to the upper and lower electrodes.

The RF powers may be supplied to the upper and lower electrodes from a plurality of RF power suppliers.

In accordance with yet another aspect of the present invention, there is provided a semiconductor substrate processing apparatus, including: a vacuum chamber to receive a semiconductor substrate; upper and lower electrodes disposed within the vacuum chamber; a high frequency power supplier connected to the upper and lower electrodes to supply high frequency RF (radio frequency) powers to the upper and lower electrodes; a low frequency power supplier connected to the lower electrode to supply a low frequency RF power to the lower electrode; and a controller to control a power ratio of the RF powers supplied to the upper and lower electrodes, wherein the controller is coupled to the high frequency power supplier.

The high frequency power supplier may include a pair or more of RF power suppliers to supply the high frequency RF powers having the same frequency to the upper and lower electrodes.

Each of the high frequency power suppliers may have a usable frequency of 2 MHz or more.

The low frequency power supplier may have a usable frequency lower than 2 MHz.

In accordance with one aspect of the present invention, there is provided a semiconductor substrate processing apparatus, the apparatus including a controller to control a power ratio of RF (radio frequency) powers having the same frequency applied to upper and lower electrodes in a vacuum chamber for receiving a semiconductor substrate.

A low frequency power supplier may be connected to the lower electrode and supplying a frequency lower than that of RF powers to the lower electrode.

The low frequency power supplier has a usable frequency lower than 2 MHz.

The apparatus of claim 13, wherein the RF powers have a usable frequency of 2 MHz or more.

In accordance with one aspect of the present invention, there is provided an etching and deposition method including: loading a semiconductor substrate into a vacuum chamber; supplying RF (radio frequency) powers having the same frequencies to upper and lower electrodes disposed within the vacuum chamber; and controlling a power ratio of the RF powers supplied to the upper and lower electrodes. A method may also supply a low frequency power to the lower electrode, wherein the low frequency power has a frequency lower than that of the RF powers.

A computer readable medium storing instructions to control at least one processor to performs of the present invention.

### BRIEF DESCRIPTION OF THE DRAWINGS

These and/or other aspects, features, and advantages of the invention will become apparent and more readily appreciated from the following description of exemplary embodiments, taken in conjunction with the accompanying drawings, of which:

FIG. 1A illustrates one example of an RF power supply system for a conventional semiconductor substrate processing apparatus;

FIG. 1B illustrates an etching uniformity by the RF power supply system of FIG. 1A;

FIG. 2A illustrates another example of an RF power supply system for the conventional semiconductor substrate processing apparatus;

FIG. 2B illustrates an etching uniformity by the RF power supply system of FIG. 2A;

FIG. 3 is a block diagram illustrating the construction of an RF power supply system for a semiconductor substrate processing apparatus according to an exemplary embodiment of the present invention;

FIG. 4 is a table showing change in etching uniformity resulting from change in RF power ratio of the semiconductor substrate processing apparatus according to an exemplary embodiment of the present invention;

FIG. 5 is a graphical representation depicting a relation between an etching uniformity and an RF power ratio of the semiconductor substrate processing apparatus according to an exemplary embodiment of the present invention;

FIG. 6 is a table showing a relation between an etching ratio and an etching uniformity according to RF power ratios of the semiconductor substrate processing apparatus according to an exemplary embodiment of the present Invention; and

FIG. 7 is a flow diagram illustrating an etching and deposition method according to an exemplary embodiment of the present invention.

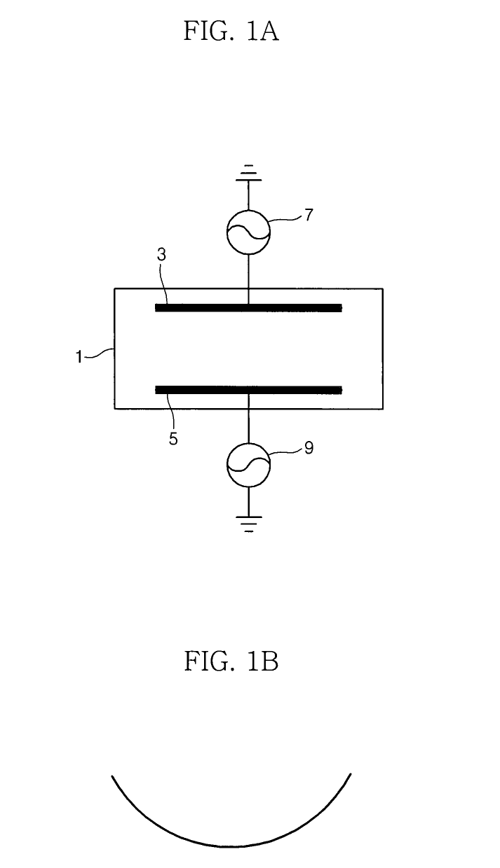

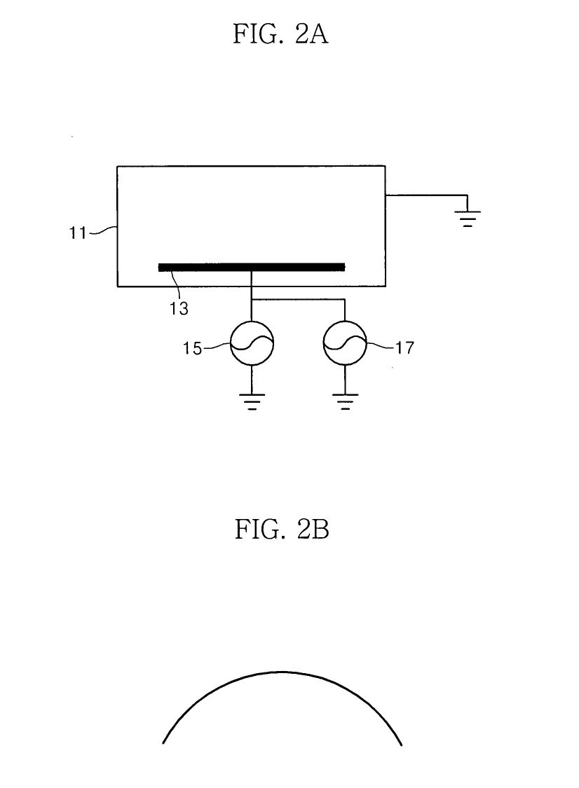

### DETAILED DESCRIPTION OF THE PREFERRED EMBODIMENTS

Reference will now be made in detail to exemplary embodiments of the present invention, examples of which are illustrated in the accompanying drawings, wherein like reference numerals refer to the like elements throughout. Exemplary embodiments are described below to explain the present invention by referring to the figures.

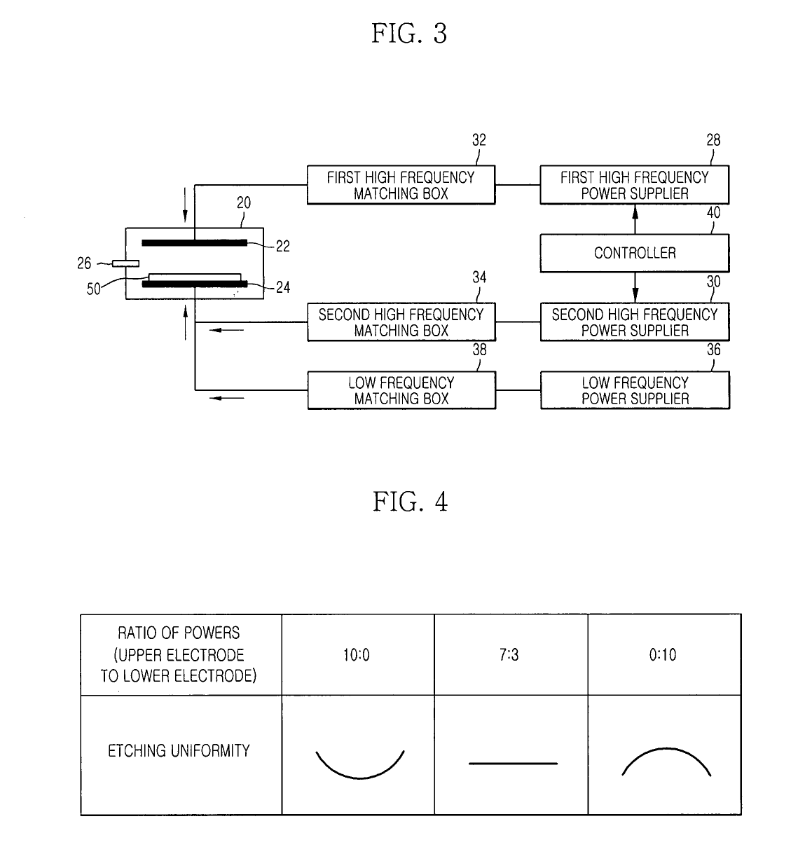

FIG. 3 is a block diagram illustrating the construction of an RF (radio frequency) power supply system for a semiconductor substrate processing apparatus according to an exemplary embodiment of the present invention.

Referring to FIG. 3, the semiconductor substrate processing apparatus according to an exemplary embodiment of the invention includes a vacuum chamber 20, upper and lower electrodes 22 and 24, a gas supplier 26, an RF power supplier, and a controller 40.

The vacuum chamber 20 is a process chamber in which a semiconductor manufacturing process is performed by plasma. In the vacuum chamber 20, a supplied gas is excited to plasma by application of an RF power, and is used for an etching process of a semiconductor substrate 50 loaded into the vacuum chamber 20.

The upper electrode 22 is a plate-shaped conductor, which is disposed at an upper portion of the vacuum chamber 20 and which supplies the RF power into the vacuum chamber 20 in order to excite the supplied gas to the plasma.

The lower electrode 24 is another plate-shaped conductor, which is disposed in parallel to the upper electrode 22 at a lower portion of the vacuum chamber 20, and which supplies the RF power into the vacuum chamber 20 as in the upper electrode 22 in order to excite the supplied gas to the plasma while allowing a processing target including the semiconductor substrate 50 to be located thereon.

The gas supplier 26 supplies the gas for processing the semiconductor substrate 50 which is loaded into the vacuum chamber 20.

The RF power supplier serves to supply RF powers preferably in the range of several kHz˜several GHz to the upper and lower electrodes 22 and 24.

The RF power supplier includes first and second high frequency power suppliers 28 and 30 connected to the upper and lower electrodes 22 and 24 to supply higher frequency powers of 2 MHz or more to the upper and lower electrodes 22 and 24, first and second high frequency matching boxes 32 and 34 to match impedances of the higher frequency powers in order to allow a maximum power of the RF powers supplied from the first and second high frequency power suppliers 28 and 30 to be transferred to the upper and lower electrodes 22 and 24, a low frequency power supplier 36 connected to the lower electrode 24 to supply an RF power, which has a lower frequency than that of the higher frequency powers from the first and second high frequency power suppliers 28 and 30, to the lower electrode 24, and a low frequency matching box 38 to match impedance of the lower frequency in order to allow a maximum power of the RF power supplied from the lower frequency power supplier 36 to be transferred to the lower electrode 24.

The controller 40 serves to control a power supply ratio of the first and second high frequency power suppliers 28 and 30 in order to control a power ratio of the RF powers supplied to the upper and lower electrodes 22 and 24. To this end, the controller 40 controls the first and second high frequency power suppliers 28 and 30 in order to control amounts of RF powers and a ratio of the RF powers supplied to the upper and lower electrodes 22 and 24 disposed within the vacuum chamber 20.

Operation and effect of the semiconductor substrate processing apparatus of an exemplary embodiment of the present invention will be described hereinafter.

Unlike the conventional RF power supply system, the RF power supply system for the semiconductor substrate processing apparatus according to an exemplary embodiment of the present invention supplies RF powers having the same high frequency to the upper and lower electrodes 22 and 24, and changes an etching uniformity by controlling a power ratio of the high frequency RF powers supplied to the upper and lower electrodes 22 and 24, thereby enabling adjustment of the etching (or deposition) uniformity according to change in conditions of a semiconductor substrate process.

As a semiconductor manufacturing process is performed, a processing gas is supplied from a gas supplier 26 to the vacuum chamber 20 via operation of a switch (not shown), and RF powers are supplied from the first and second high frequency power suppliers 28 and 30, and from the low frequency power supplier 36 to the upper and lower electrodes 22 and 24 in the vacuum chamber 20 through the first and second high frequency matching boxes 32 and 34, and the low frequency matching box 38.

Accordingly, the supplied gas is excited to plasma in the vacuum chamber 20, and an etching (or deposition) process is performed with respect to a semiconductor substrate 50 located on the lower substrate 24 by using ions and electrons of the plasma.

At this time, the controller 40 can change a density distribution of the ions and the electrons of the plasma by controlling the ratio of high frequency RF powers supplied to the upper and lower electrodes 22 and 24, which influences the etching (or deposition) process with respect to the semiconductor substrate 50 located on the lower substrate 24, thereby allowing adjustment of an etching (or deposition) uniformity and an etching rate (or deposition rate).

FIG. 4 is a table showing change in etching uniformity resulting from change in RF power ratio of the semiconductor substrate processing apparatus according to an exemplary embodiment of the present invention, in which the ratio of RF powers supplied from the RF power supply system to the upper and lower electrodes 22 and 24 are adjusted to 10:0, 7:3, and 0:10, respectively. From this table, it can be appreciated that, when the ratio of the RF powers supplied to the upper and lower electrodes 22 and 24 is 7:3, the etching uniformity is further enhanced than other ratios of the RF powers.

As such, since the RF power supply system of the semiconductor substrate processing apparatus according an exemplary embodiment of to the present invention can control the etching rate by controlling the ratio of the RF powers (i.e., power ratio) when supplying the high frequency RF powers having the same frequency to the upper and lower electrodes 22 and 24, it is possible to control process parameters by changing only the power ratio according to change in conditions of the process without changing hardware.

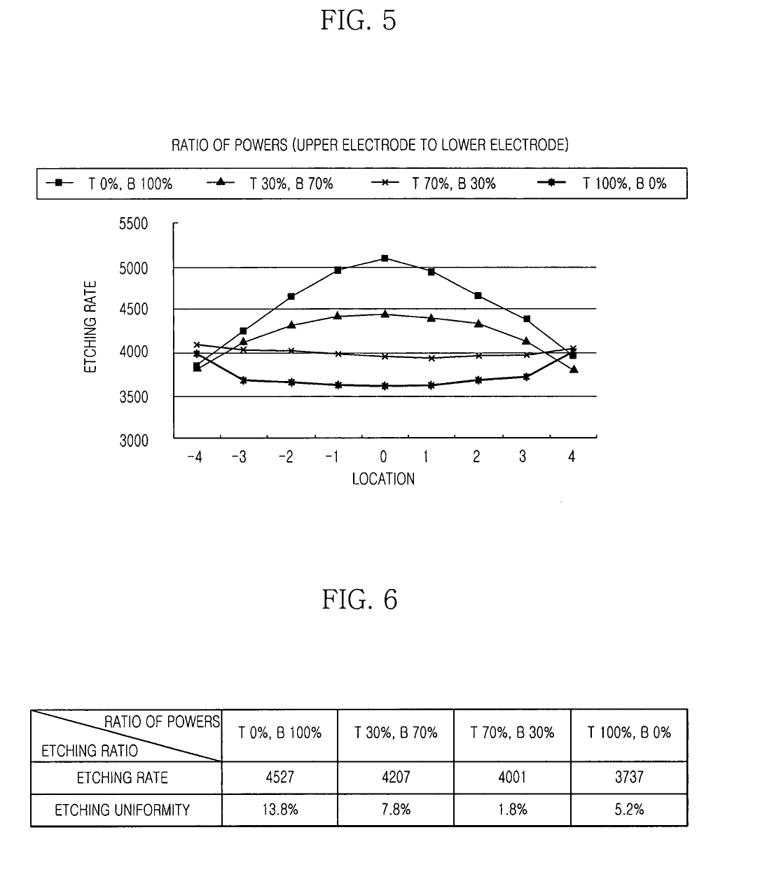

FIG. 5 is a graphical representation depicting a relation between an etching uniformity and an RF power ratio of the semiconductor substrate processing apparatus according to an exemplary embodiment of the present invention. From FIG. 5, it can be appreciated that, when RF powers are supplied to the upper and lower electrodes 22 and 24 at 70% and 30%, respectively, the etching rate according to locations is constantly maintained, and that the etching rate can be variously controlled according to the ratio of RF powers supplied to the upper and lower electrodes 22 and 24.

FIG. 6 is a table showing a relation between an etching ratio and an etching uniformity according to RF power ratios shown in FIGS. 4 and 5. As can be seen from FIG. 6, it is possible to control characteristics of the process by controlling the power ratio while applying the same frequency to the upper and lower electrodes 22 and 24.

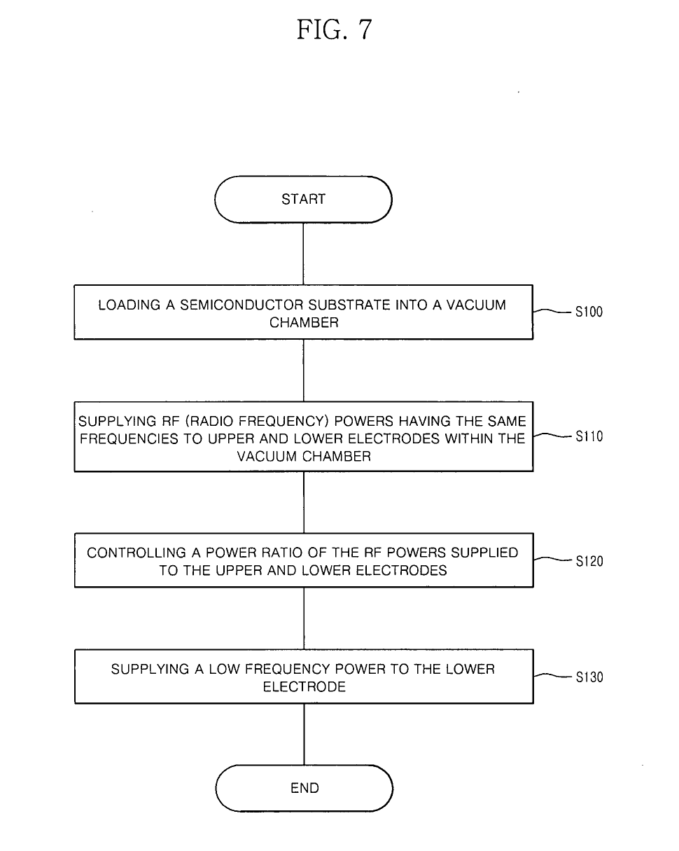

FIG. 7 is a flow diagram illustrating an etching and/or deposition method according to an exemplary embodiment of the present invention. As shown in FIG. 7, a semiconductor substrate is loaded into a vacuum chamber (S100). In operation S110, RF (Radio Frequency) powers having the same frequencies are supplied to upper and lower electrodes within the vacuum chamber. The power ratio of the RF powers supplied to the upper and lower electrodes is controlled (S120), and a low frequency power may be supplied to the lower electrode (S130). The operations S100 through S130 may be performed in any order and two or more of these operations may be performed simultaneously.

As apparent from the above description, the semiconductor substrate processing apparatus and method of exemplary embodiments of the present invention provide an advantageous effect in that the processing uniformity of the semiconductor substrate can be enhanced by supplying RF powers having the same frequency to upper and lower electrodes serving to generate different degrees of uniformity, and controlling a power ratio of the RF powers.

In addition, the semiconductor substrate processing apparatus and method of exemplary embodiments of the present invention provide another advantageous effect in that process parameters can be controlled by changing the power ratio of RF powers according to change in conditions of the process without changing hardware.

In addition to the above-described exemplary embodiments, exemplary embodiments of the present invention can also be implemented by executing computer readable code/instructions in/on a medium/media, e.g., a computer readable medium/media. The medium/media can correspond to any medium/media permitting the storing and/or transmission of the computer readable code/instructions. The medium/media may also include, alone or in combination with the computer readable code/instructions, data files, data structures, and the like. Examples of code/instructions include both machine code, such as produced by a compiler, and files containing higher level code that may be executed by a computing device and the like using an interpreter.

The computer readable code/instructions can be recorded/transferred in/on a medium/media in a variety of ways, with examples of the medium/media including magnetic storage media (e.g., floppy disks, hard disks, magnetic tapes, etc.), optical media (e.g., CD-ROMs, or DVDs), magneto-optical media (e.g., floptical disks), hardware storage devices (e.g., read only memory media, random access memory media, flash memories, etc.) and storage/transmission media such as carrier waves transmitting signals, which may include computer readable code/instructions, data files, data structures, etc. Examples of storage/transmission media may include wired and/or wireless transmission media. For example, storage/transmission media may include optical wires/lines, waveguides, and metallic wires/lines, etc. including a carrier wave transmitting signals specifying instructions, data structures, data files, etc. The medium/media may also be a distributed network, so that the computer readable code/instructions are stored/transferred and executed in a distributed fashion. The medium/media may also be the Internet. The computer readable code/instructions may be executed by one or more processors. An example of one or more processors may be controller 40. The computer readable code/instructions may also be executed and/or embodied in at least one application specific integrated circuit (ASIC) or Field Programmable Gate Array (FPGA). The controller 40 may be one or more ASICs or FPGAs.

In addition, hardware devices may be configured to act as one or more software modules in order to perform the operations of the above-described exemplary embodiments.

The term “module,” as used herein, denotes, but is not limited to, a software or hardware component, which performs certain tasks. A module may advantageously be configured to reside on the addressable storage medium/media and configured to execute on one or more processors. Thus, a module may include, by way of example, components, such as software components, object-oriented software components, class components and task components, processes, functions, attributes, procedures, subroutines, segments of program code, drivers, firmware, microcode, circuitry, data, databases, data structures, tables, arrays, and variables. The functionality provided for in the components and modules may be combined into fewer components and modules or further separated into additional components and modules. In addition, the components and the modules can operate at least one processor (e.g. central processing unit (CPU)) provided in a device

The computer readable code/instructions and computer readable medium/media may be those specially designed and constructed for the purposes of the present invention, or they may be of the kind well-known and available to those skilled in the art of computer hardware and/or computer software.

Although a few exemplary embodiments of the present invention have been shown and described, it would be appreciated by those skilled in the art that changes may be made in these exemplary embodiments without departing from the principles and spirit of the invention, the scope of which is defined in the claims and their equivalents.

What is claimed is:

1. A semiconductor substrate processing apparatus, comprising:
a vacuum chamber to receive a semiconductor substrate;
upper and lower electrodes disposed within the vacuum chamber;
an RF power supplier to supply RF (radio frequency) powers having the same frequency to the upper and lower electrodes; and
a controller to control a power ratio of the RF powers supplied from the RF power supplier to the upper and lower electrodes.

2. The apparatus according to claim 1, wherein the RF power supplier comprises a pair or more of high frequency power suppliers connected to the upper and lower electrodes.

3. The apparatus according to claim 2, wherein each of the high frequency power suppliers has a usable frequency of 2 MHz or more.

4. The apparatus according to claim 2, wherein the RF power supplier further comprises a low frequency power supplier connected to the lower electrode.

5. The apparatus according to claim 4, wherein the low frequency power supplier has a usable frequency lower than that of the high frequency power suppliers.

6. A semiconductor substrate processing apparatus, comprising:
a vacuum chamber to receive a semiconductor substrate;
a gas supplier to supply gas for processing the semiconductor substrate in the vacuum chamber;
a RF (radio frequency) power supplier to supply RF powers to generate plasma from the supplied gas; and
a controller to control amounts of RF powers and a ratio of the RF powers supplied to upper and lower electrodes disposed in the vacuum chamber.

7. The apparatus according to claim 6, wherein the controller allows high RF powers having the same frequency to be supplied to the upper and lower electrodes.

8. The apparatus according to claim 7, wherein the RF powers are supplied to the upper and lower electrodes from a plurality of RF power suppliers.

9. A semiconductor substrate processing apparatus, comprising:
a vacuum chamber to receive a semiconductor substrate;
upper and lower electrodes disposed within the vacuum chamber;
a high frequency power supplier connected to the upper and lower electrodes to supply high frequency RF (radio frequency) powers to the upper and lower electrodes;
a low frequency power supplier connected to the lower electrode to supply a low frequency RF power to the lower electrode; and
a controller to control a power ratio of the RF powers supplied to the upper and lower electrodes, wherein the controller is coupled to the high frequency power supplier.

10. The apparatus according to claim 9, wherein the high frequency power supplier comprises a pair or more of RF power suppliers to supply the high frequency RF powers having the same frequency to the upper and lower electrodes.

11. The apparatus according to claim 9, wherein each of the high frequency power suppliers has a usable frequency of 2 MHz or more.

12. The apparatus according to claim 9, wherein the low frequency power supplier has a usable frequency lower than 2 MHz.

13. An apparatus comprising a controller to control a power ratio of RF (radio frequency) powers having the same frequency applied to upper and lower electrodes in a vacuum chamber for receiving a semiconductor substrate.

14. The apparatus of claim 13, further comprising a low frequency power supplier connected to the lower electrode and supplying a frequency lower than that of RF powers to the lower electrode.

15. The apparatus of claim 14, wherein the low frequency power supplier has a usable frequency lower than 2 MHz.

16. The apparatus of claim 13, wherein the RF powers have a usable frequency of 2 MHz or more.

17. An etching and deposition method comprising:
loading a semiconductor substrate into a vacuum chamber;
supplying RF (radio frequency) powers having the same frequencies to upper and lower electrodes disposed within the vacuum chamber; and
controlling a power ratio of the RF powers supplied to the upper and lower electrodes.

18. The method of claim 17, further comprising supplying a low frequency power to the lower electrode, wherein the low frequency power has a frequency lower than that of the RF powers.

19. A computer readable medium storing instructions to control at least one processor to perform the method of claim 17.

20. A computer readable medium storing instructions to control at least one processor to perform the method of claim 18.
